(19) United States
(12) Patent Application Publication
(10) Pub. No.: US 2007/0148945 A1
(43) Pub. Date: Jun. 28, 2007

(54) METHOD FOR FORMING A FINE PATTERN OF A SEMICONDUCTOR DEVICE

(76) Inventor: Eui Kyu Ryou, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,812

(22) Filed: Dec. 27, 2006

(30) Foreign Application Priority Data
Dec. 28, 2005 (KR) 10-2005-0131524

(51) Int. Cl. H01L 21/44; H01L 23/48

(52) U.S. Cl. 438/597; 257/773

(57) ABSTRACT

Embodiments relate to a method for forming a fine pattern of a semiconductor device. According to embodiments, the method for forming a fine pattern of a semiconductor device may include forming a first oxide layer on a semiconductor substrate, forming a photoresist pattern on the first oxide layer, forming a second oxide layer on the first oxide layer exposed by the photoresist pattern, exposing the first oxide layer through a gap of the second oxide layer by removing the photoresist pattern, forming a spacer layer on sidewalls of the second oxide layer exposing the first oxide layer, forming a target layer for a fine pattern on the first oxide layer exposed by the second oxide layer and the spacer layer, and forming a fine pattern having a pitch reduced within a thickness range of the spacer layer by performing planarization with respect to the second oxide layer, the spacer layer, and the target layer for the fine pattern.

The present application claims priority under 35 U.S.C. 119 and 35 U.S.C. 365 to Korean Patent Application No. 10-2005-0131524 (filed on Dec. 28, 2005), which is hereby incorporated by reference in its entirety.

### BACKGROUND

As semiconductor devices become more highly integrated, an area of a unit cell may be reduced. The reduction in area of the unit cell may mean that the size of each element formed in the cell may also be reduced. Not only might a size of a transistor or a capacitor be reduced, but a width of an interconnection, an interval between interconnections, and a size of a contact that may electrically connect an upper element to a lower element may also be miniaturized. To manufacture such miniaturized elements, several process conditions may be provided. For example, to form fine patterns, a photolithography technology that may be capable of supporting the delicate formation of a fine pattern may be necessary.

In a related art method for forming a fine pattern using photolithography technology, a photoresist layer may be provided on a target layer to be patterned. And exposure and developing process may be performed using photolithography equipment. This may form a photoresist pattern that may cover a portion of the target layer.

An exposed portion of the target layer may then be removed, for example through an etching process using the photoresist pattern as an etching mask. The photoresist pattern may also be removed in this process. Accordingly, only a portion of the target layer covered with the photoresist pattern may remain as a pattern.

When forming such a fine pattern, however, a width of the fine pattern may be determined by the width of the photoresist pattern. Accordingly, to form the fine pattern by patterning a target layer, a photoresist pattern having a width corresponding to the width of the fine pattern may be formed. However, photolithography equipment and fabrication technology may not be able to support the significantly narrowed pitch of the fine pattern.

### SUMMARY

Embodiments relate to a method for manufacturing a semiconductor device. Embodiments relate to a method for forming a fine pattern of a semiconductor device.

Embodiments relate to a method for forming a fine pattern of a semiconductor device that may be capable of forming a fine pattern which may not be realized using photolithography equipment.

In embodiments, a method for forming a fine pattern of a semiconductor device, may include forming a first oxide layer on a semiconductor substrate, forming a photoresist pattern on the first oxide layer, forming a second oxide layer on the first oxide layer exposed by the photoresist pattern, exposing the first oxide layer through a gap of the second oxide layer by removing the photoresist pattern, forming a spacer layer on sidewalls of the second oxide layer exposing the first oxide layer, forming a target layer for a fine pattern on the first oxide layer exposed by the second oxide layer and the spacer layer; and forming a fine pattern having a pitch reduced within a thickness range of the spacer layer by performing planarization with respect to the second oxide layer, the spacer layer, and the target layer for the fine pattern.

In embodiments, second oxide layer may include a liquid oxide layer using the first oxide layer as a seed layer. Embodiments, forming the spacer layer may include forming a material layer for a spacer on the first oxide layer and the second oxide layer, and performing an anisotropic dry etching process for the material layer for the spacer such that the surface of the first and second oxide layers may be exposed.

In embodiments, and etch-back process may be performed instead of a chemical mechanical polishing process. In embodiments, the target layer for the fine pattern may include a conductive layer or a metal layer.

### BRIEF DESCRIPTION OF THE DRAWINGS

FIGS. 1 to 3 are example sectional views illustrating a method for forming a fine pattern of a semiconductor device according to embodiments.

### DETAILED DESCRIPTION OF EMBODIMENTS

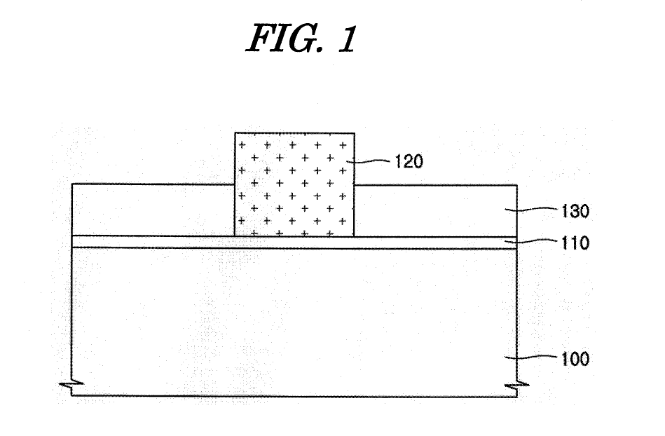

Referring to FIG. 1, first oxide layer 110 may be formed on semiconductor substrate 100, which may be a silicon substrate. Oxide layer 110 may serve as a seed layer in a subsequent oxidation process. Accordingly, oxide layer 110 may be formed with a small thickness. Photoresist pattern 120 may be formed on first oxide layer 110. In embodiments, a photoresist layer may be formed on first oxide layer 110, and then an exposure and development process may be performed through a photolithography process. Photoresist pattern 120 may have a pitch according to a performance of photolithography equipment. First oxide layer 110 may be exposed at both sides of photoresist pattern 120 by photoresist pattern 120. In embodiments, second oxide layer 130 may be formed on first oxide layer 110. Second oxide layer 130 may be a liquid oxide layer using first oxide layer 110 as a seed layer. A thickness of second oxide layer 130 may be determined by taking the thickness of a fine pattern to be formed into account. In embodiments, second oxide layer 130 may be formed with an initial thickness greater than the thickness of the fine pattern to be formed. A planarization process can be performed. Hence, the thickness of second oxide layer 130 may be identical to the thickness of the fine pattern after both have been subjected to a planarization process.

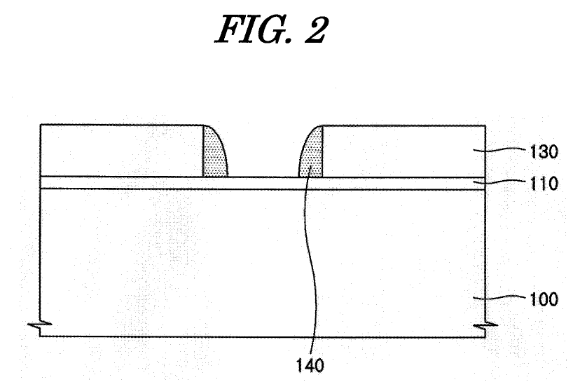

Referring to FIG. 2, photoresist pattern 120 may be stripped through an ashing process. A surface of first oxide layer 110 may be exposed through a gap of second oxide layer 130. In embodiments, spacer layer 140 may be formed at both sidewalls of second oxide layer 130. Spacer layer 140 may include an insulating layer, such as a nitride layer or an oxide layer. To form spacer layer 140, an insulating layer (not shown) for a spacer may be formed on first oxide layer 110 and second oxide layer 130. Then, an anisotropic dry etching process may be performed with respect to the insulating layer for the spacer. This may remove the insulating layer for the spacer from the upper surface of first oxide layer 110 and second oxide layer 130. Accordingly, spacer layer 140, which may be positioned on the sidewalls of second oxide layer 130, may be formed.

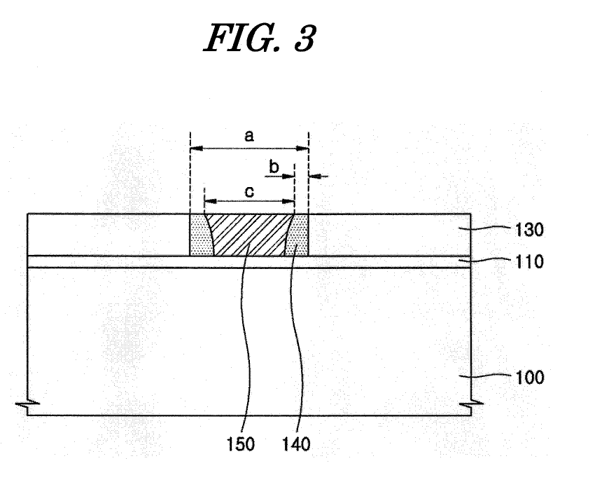

Referring to FIG. 3, a target layer for a fine pattern may be formed on a surface of the resultant structure formed with spacer layer 140. The target layer for the fine pattern may include a metal layer or a conductive layer such as a polysilicon layer. In embodiments, the target layer for the fine pattern may include other layers in addition to the conductive layer and the metal layer. A planarization process may then be performed, for example through a chemical mechanical polishing (CMP) process. An upper part of second oxide layer 130 and spacer layer 140 may thus be exposed. According to the planarization process, fine pattern 150 may be formed between spacer layers 140. In embodiments, an etch-back process may be performed instead of the chemical mechanical polishing (CMP) process.

Pitch (c) of fine pattern 150 may be narrower than a pitch of photoresist pattern 120, that is, width (a) of the gap of second oxide layer 130. Pitch (c) may deviate from a pitch range to be obtained through photolithography equipment. Such a deviation degree of pitch (c) may be determined depending on a thickness of spacer layer 140. In embodiments, pitch (c) of fine pattern 150 may be narrower than width (a) of the gap of second oxide layer 130 by the thickness of spacer layer 140. Generally, since thickness (b) of spacer layer 140 is relatively thin at an upper part thereof and relatively thick at a lower part thereof, thickness (b) of spacer layer 140 may be determined through the planarization process, and pitch (c) of fine pattern 150 may be determined by the thickness (b) of spacer layer 140. Accordingly, it may be possible to delicately and finely adjust a pitch of fine pattern 150 by adjusting a thickness removed through the planarization process. In addition, an alignment margin may be increased by thickness (b) of spacer layer 140.

As described above, according to embodiments, it may be possible to form a fine pattern having a pitch reduced within a range of the thickness of the spacer layer while overcoming the limitation of photolithography equipment. In addition, an alignment margin may be increased by the thickness of the spacer layer, so it may be possible to reduce an amount of defects during the manufacturing process.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a first oxide layer and a second oxide layer over a semiconductor substrate, the second oxide layer having a gap exposing the first oxide layer;
forming a spacer layer on sidewalls of the gap of the second oxide layer; and
forming a fine pattern by filling the gap with a least one of a poly silicon layer and a metal layer.

2. The method of claim 1, further comprising:
forming the first oxide layer over the semiconductor substrate;
forming a photoresist pattern over the first oxide layer;
forming the second oxide layer over the first oxide layer exposed by the photoresist pattern; and
exposing the first oxide layer through a gap of the second oxide layer by removing the photoresist pattern.

3. The method of claim 1, wherein forming the fine pattern comprises forming a target layer for the fine pattern over the first oxide layer in a region exposed by the second oxide layer and the spacer layer, and planarizing at least the target layer.

4. The method of claim 3, were in a pitch of the fine pattern is adjusted by further planarizing the target layer and the second oxide layer including the sidewalls.

5. The method of claim 4, wherein the sidewalls have a first width in a top portion of the sidewalls and a second width at a bottom portion of the sidewalls.

6. The method of claim 3, wherein planarizing the target layer comprises at least one of etching and chemical mechanical polishing.

7. The method of claim 1, wherein the second oxide layer comprises a liquid oxide layer using the first oxide layer as a seed layer.

8. The method of claim 7, were in the second oxide layer has a greater thickness than the first oxide later.

9. The method of claim 1, wherein forming the spacer layer comprises:
forming a material layer for the spacer over the first oxide layer and the second oxide layer; and
performing an anisotropic dry etching process for the material layer for the spacer such that the surface of the first and second oxide layers is exposed.

10. A device, comprising:
a first oxide layer formed over a semiconductor substrate;
a second oxide layer formed over the first oxide layer, having a gap therein;
sidewalls formed within the gap of the second oxide layer; and
a target layer formed within the gap between the sidewalls, wherein the target layer forms a fine pattern.

11. The device of claim 10, wherein a width of the fine pattern is adjusted by planarizing the second oxide layer, the sidewalls, and the target layer.

12. The device of claim 11, wherein the sidewalls have a first width at a top portion of the sidewalls in a second width at a bottom portion of the sidewalls.

13. The device of claim 11, wherein planarizing comprises at least one of performing an etching process and performing a chemical mechanical polishing process.

14. The device of claim 10, wherein the second oxide layer has a greater thickness than the first oxide layer.

15. The device of claim 14, wherein the second oxide layer comprises a liquid oxide layer using the first oxide layer as a seed layer.

16. The device of claim 10, wherein the target layer comprises at least one of a polysilicon layer, a metallic layer, and a conductive layer.

17. A method, comprising:
forming a first oxide layer over a semiconductor substrate;
forming a photoresist pattern over the first oxide layer;
forming a second oxide layer over the first oxide layer exposed by the photoresist pattern;
exposing the first oxide layer through a gap of the second oxide layer by removing the photoresist pattern;
forming a spacer layer on sidewalls of the second oxide layer exposing the first oxide layer;
forming a target layer for a fine pattern over the first oxide layer exposed by the second oxide layer and the spacer layer; and
forming a fine pattern having a pitch reduced within a thickness range of the spacer layer by performing planarization with respect to the second oxide layer, the spacer layer, and the target layer for the fine pattern.

18. The method of claim 17, wherein the planarization comprises at least one of etching and chemical mechanical polishing.

19. The method of claim 17, wherein a width of a bottom portion of the sidewalls is greater than a width of a top portion of the sidewalls.
